(19) United States
(12) Patent Application Publication
(10) Pub. No.: US 2020/0395501 A1
(43) Pub. Date: Dec. 17, 2020

(54) SUPERLUMINESCENT DIODE

(71) Applicant: HAMAMATSU PHOTONICS K.K., Hamamatsu-shi, Shizuoka (JP)

(72) Inventors: Masamichi YAMANISHI, Hamamatsu-shi, Shizuoka (JP); Toru HIROHATA, Hamamatsu-shi, Shizuoka (JP); Kazunori TANAKA, Hamamatsu-shi, Shizuoka (JP); Kazuue FUJITA, Hamamatsu-shi, Shizuoka (JP); Akira HIGUCHI, Hamamatsu-shi, Shizuoka (JP)

(73) Assignee: HAMAMATSU PHOTONICS K.K., Hamamatsu-shi, Shizuoka (JP)

(21) Appl. No.: 16/769,295

(22) PCT Filed: Nov. 29, 2018
(86) PCT No.: PCT/JP2018/044055

§ 371 Date: Jun. 3, 2020

(30) Foreign Application Priority Data
Dec. 5, 2017 (JP) 2017-233301

(51) Int. Cl. H01L 33/00; H01L 33/14; G02B 6/10; H01L 33/26

(52) U.S. Cl. CPC H01L 33/0045; H01L 33/26; G02B 6/10; H01L 33/14

(57) ABSTRACT

Provided is a superluminescent diode including an optical waveguide body configured as a double heterostructure including an active layer and a first clad layer and a second clad layer interposing the active layer. When a direction perpendicular to both an optical waveguide direction of the optical waveguide body and a facing direction of the first clad layer and the second clad layer is set as a width direction, the active layer is provided with a limitation region extending along the optical waveguide direction and partitioning the active layer in the width direction. Carriers are less likely to be generated in the limitation region than in a region other than the limitation region in the active layer.

### TECHNICAL FIELD

The present disclosure relates to a superluminescent diode.

### BACKGROUND ART

A superluminescent diode (hereinafter, also referred to as an SLD) has been attracting attention as a light source that generate output light having excellent light condensing property and having a wide spectrum. As an SLD, for example, Patent Literature 1 discloses an end-face light emitting diode in which an optical waveguide body having a double heterostructure is electrically separated into a light emitting region and a light loss region by an ion implantation region.

### CITATION LIST

### Patent Literature

Patent Literature 1: Japanese Unexamined Patent Publication No. H4-259262

### SUMMARY OF INVENTION

### Technical Problem

In the above-described SLD, it is considered that the optical waveguide body is formed to be wide in order to achieve high output. However, when the width of the optical waveguide body increases, light beams of a plurality of modes are mixed and interfere with each other, so that the intensity distribution of output light on the light emission face may be disturbed.

An object of one aspect of the present disclosure is to provide a superluminescent diode that can achieve both high output and generation of output light having a good beam pattern.

### Solution to Problem

A superluminescent diode according to one aspect of the present disclosure includes an optical waveguide body configured as a double heterostructure including an active layer and a first clad layer and a second clad layer interposing the active layer, in which, when a direction perpendicular to both an optical waveguide direction of the optical waveguide body and a facing direction of the first clad layer and the second clad layer is set as a width direction, the active layer is provided with a limitation region extending along the optical waveguide direction and partitioning the active layer in the width direction, and in which carriers are less likely to be generated in the limitation region than in a region other than the limitation region in the active layer.

In the superluminescent diode, the limitation region extending along the optical waveguide direction and partitioning the active layer in the width direction is provided in the active layer. Carriers are less likely to be generated in the limitation region than in a region other than the limitation region in the active layer. In the superluminescent diode, even in a case where the optical waveguide body is formed to be wide in order to achieve high output, by disposing the limitation region so that the mode occurring in the active layer is regulated, the output light having a good beam pattern can be generated. Therefore, according to the superluminescent diode, it is possible to achieve both high output and generation of output light having a good beam pattern.

In the superluminescent diode according to one aspect of the present disclosure, a plurality of the limitation regions may be provided, and the plurality of limitation regions may be disposed symmetrically with respect to a plane passing through a center of the active layer and perpendicular to the width direction. In this case, the mode occurring in the active layer can be appropriately regulated by the limitation region.

In the superluminescent diode according to one aspect of the present disclosure, a plurality of the limitation regions may be provided, and the plurality of limitation regions may include a pair of the limitation regions disposed along both edges of the active layer in the width direction respectively. In this case, the mode occurring in the active layer can be more appropriately regulated by the limitation region.

In the superluminescent diode according to one aspect of the present disclosure, the limitation region may be disposed at a position that divides the active layer at equal intervals in the width direction. In this case, the mode occurring in the active layer can be more appropriately regulated by the limitation region.

In the superluminescent diode according to one aspect of the present disclosure, the limitation region may reach a light emission face of the optical waveguide body in the optical waveguide direction. In this case, the mode can be regulated in a region including the light emission face side of the active layer, and output light having a better beam pattern can be generated.

In the superluminescent diode according to one aspect of the present disclosure, the limitation region reaches each of the first clad layer and the second clad layer from the active layer in the facing direction. In this case, the mode occurring in the active layer can be more appropriately regulated by the limitation region.

In the superluminescent diode according to one aspect of the present disclosure, the limitation region may be configured with an ion implantation region or an impurity diffusion region. In this case, generation of carriers in the limitation region can be appropriately limited.

In the superluminescent diode according to one aspect of the present disclosure, the optical waveguide direction may be a direction extending straight. In this case, the output light having a better beam pattern can be generated.

In the superluminescent diode according to one aspect of the present disclosure, a light emission face of the optical waveguide body may be a face perpendicular to the optical waveguide direction. In this case, the output light having a better beam pattern can be generated.

The superluminescent diode according to one aspect of the present disclosure may further include a substrate provided with the optical waveguide body, in which the optical waveguide body may be configured as a ridge structure on the substrate. In this case, the handling of the superluminescent diode can be facilitated, and the configuration of the optical waveguide body can be simplified.

The superluminescent diode according to one aspect of the present disclosure may further include a first electrode and a second electrode that are provided on the second clad layer so as to be arranged along the optical waveguide direction; and at least one third electrode that faces the first electrode and the second electrode with the optical waveguide body interposed therebetween, in which the optical waveguide body may be provided with a separation region that optically connects a first region below the first electrode and a second region below the second electrode and electrically separates the first region and the second region from each other. In this case, a forward bias is applied between the first electrode and at least one third electrode to allow the first region to function as a gain region, and a reverse bias is applied between the second electrode and at least one third electrode to allow the second region to function as a loss region, so that the output light having a good beam pattern can be generated.

In the superluminescent diode according to one aspect of the present disclosure, the limitation region may be provided in the first region and may not reach the second region. In this case, since the second region is not provided with a limitation region, in a state where the first region functions as a gain region and the second region functions as a loss region, light generated in the gain region can be effectively absorbed in the loss region.

The superluminescent diode according to one aspect of the present disclosure may further include a fourth electrode that is provided on the second clad layer so as to be located on a side opposite to the second electrode with respect to the first electrode in the optical waveguide direction, in which a third region below the fourth electrode may have a flare shape in which, as viewed from a direction perpendicular to the second clad layer, the width increases as the distance from the first region increases. In this case, since the light is amplified while spreading in the third region, the output light having a wide beam pattern can be generated. Furthermore, in the third region, as the width increases, the current density is reduced, and carriers are less likely to be generated, so that a new mode is less likely to occur. Therefore, according to the superluminescent diode, it is possible to generate the output light having a better beam pattern.

### Advantageous Effects of Invention

According to an embodiment of the present disclosure, it is possible to provide a superluminescent diode that can achieve both high output and generation of output light having a good beam pattern.

### BRIEF DESCRIPTION OF DRAWINGS

FIG. 1 is a perspective view illustrating a superluminescent diode according to an embodiment.

FIG. 2 is a cross-sectional view taken along line II-II illustrated in FIG. 1.

FIG. 3 is a cross-sectional view taken along line III-III illustrated in FIG. 2.

FIGS. 4(a) to 4(c) are conceptual views for describing functions and effects of the superluminescent diode according to the embodiment.

FIG. 5 is a perspective view of an optical semiconductor device according to Modified Example 1.

FIG. 6 is a conceptual view for describing functions and effects of Modified Example 1.

FIG. 7 is a perspective view of an optical semiconductor device according to Modified Example 2.

FIG. 8 is a perspective view of an optical semiconductor device according to Modified Example 3.

### DESCRIPTION OF EMBODIMENTS

Hereinafter, embodiments of the present disclosure will be described in detail with reference to the drawings. In addition, in the drawings, the same or corresponding components are denoted by the same reference numerals, and overlapping components are omitted.

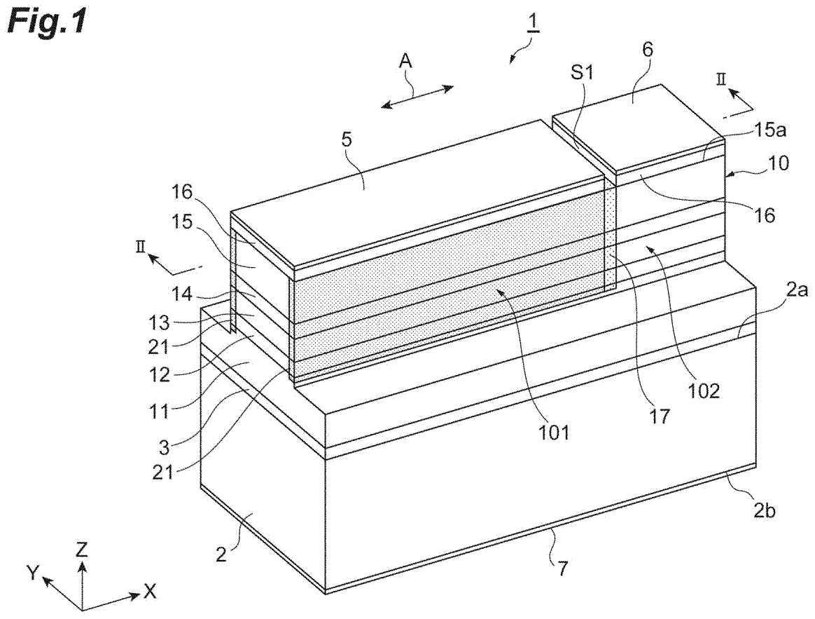

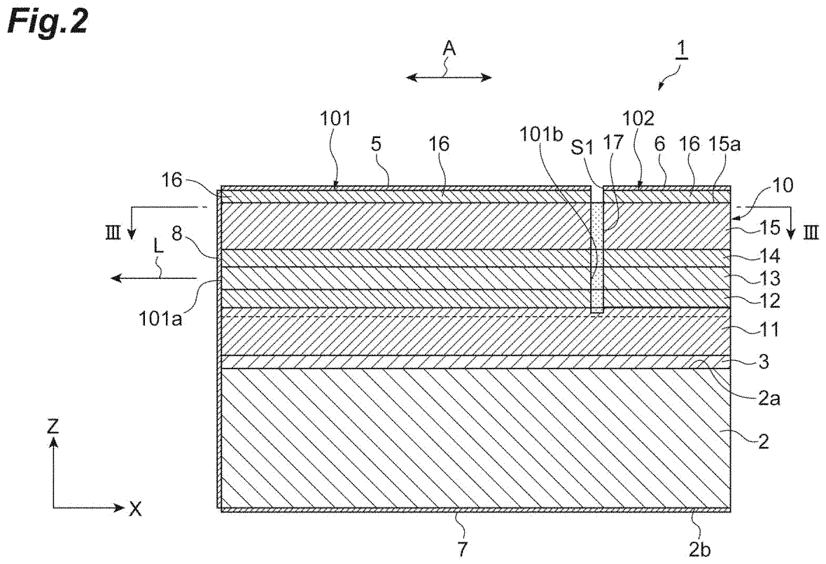

As illustrated in FIGS. 1 to 3, a superluminescent diode (SLD) 1 includes a substrate 2 and an optical waveguide body 10. The optical waveguide body 10 is provided on a front face 2a of the substrate 2 via a buffer layer 3. Each of the substrate 2 and the buffer layer 3 is made of, for example, n⁻-type GaAs. The substrate 2 has, for example, a rectangular plate shape having a length of about 1.0 to 5.0 mm, a width of about 10 to 200 μm, and a thickness of about 300 to 500 μm. Hereinafter, the length direction of the substrate 2 is referred to as an X-axis direction, the width direction of the substrate 2 is referred to as a Y-axis direction, and the thickness direction of the substrate 2 is referred to as a Z-axis direction.

The optical waveguide body 10 is configured by stacking a first clad layer 11, a first guide layer 12, an active layer 13, a second guide layer 14, a second clad layer 15, and a contact layer 16 on the buffer layer 3 in this order. The optical waveguide body 10 is configured as a double heterostructure including the active layer 13 and the first clad layer 11 and the second clad layer 15 interposing the active layer 13. The first clad layer 11 is made of, for example, n⁻-type Al_{0.3}Ga_{0.7}As. The first guide layer 12 is made of, for example, non-doped Al_{0.25}Ga_{0.75}As. The active layer 13 has, for example, a GaAs/Al_{0.2}Ga_{0.8}As multiple-quantum-well structure. The second guide layer 14 is made of, for example, non-doped Al_{0.25}Ga_{0.75}As. The second clad layer 15 is made of, for example, p⁻-type Al_{0.3}Ga_{0.7}As. The contact layer 16 is made of, for example, p⁺-type GaAs.

The optical waveguide body 10 is formed on the substrate 2 as a ridge structure. The optical waveguide direction A of the optical waveguide body 10 is a direction that extends straight and parallel to the X-axis direction. As an example, the width of the optical waveguide body 10 is smaller than the widths of the substrate 2 and the buffer layer 3 except for a portion of the first clad layer 11 on the buffer layer 3 side. In the ridge structure portion, the optical waveguide body 10 has, for example, a rectangular plate shape (layer shape) having a length of about 0.5 to 5.0 mm, a width of about 10 to 100 μm, and a thickness of about 1 to 2 μm. The optical waveguide direction A is a direction along the center line of a cylindrical region for confining light (in the ridge structure, a region formed by the first clad layer 11, the second clad layer 15, and the air layer). In other words, the optical waveguide direction A is a direction in which the active layer 13 surrounded by the cylindrical region extends.

The SLD 1 further includes a first electrode 5, a second electrode 6, and a third electrode 7. Each of the first electrode 5 and the second electrode 6 is provided on the second clad layer 15 via the contact layer 16 and is electrically connected to the second clad layer 15 immediately below, via the contact layer 16. The third electrode 7 is provided on a back face 2b of the substrate 2 and is electrically connected to the substrate 2. The first electrode 5, the second electrode 6, and the third electrode 7 are made of, for example, an Au-based metal. The first electrode 5 and the second electrode 6 are aligned along the optical waveguide direction A. The third electrode 7 faces the first electrode 5 and the second electrode 6 with the substrate 2, the buffer layer 3, and the optical waveguide body 10 interposed therebetween.

A gap S1 extending in the Y-axis direction is formed between the first electrode 5 and the second electrode 6, and the contact layer 16 is physically separated along the gap S1. That is, the first electrode 5 and the second electrode 6 are formed by separating a metal layer formed so as to cover the entire upper surface (the front face opposite to the third electrode 7) of the optical waveguide body 10 through the gap S1. In other words, the first electrode 5 and the second electrode 6 are formed so as to cover the entire area of the upper surface of the optical waveguide body 10 except for the gap S1. In addition, the contact layer 16 is separated by the gap S1 for each portion immediately below each of the first electrode 5 and the second electrode 6.

The optical waveguide body 10 is provided with a separation region 17. In the optical waveguide body 10, the separation region 17 optically connects a first region 101 below the first electrode 5 and a second region 102 below the second electrode 6 and electrically separates the first region 101 and the second region from each other. That is, light traveling in the active layer 13 can move between the first region 101 and the second region 102 through the separation region 17.

The first region 101 is a region overlapping the first electrode 5 in the optical waveguide body 10 as viewed from the Z-axis direction and is a region interposed between the first electrode 5 and the third electrode 7 in the optical waveguide body 10. The second region 102 is a region overlapping the second electrode 6 in the optical waveguide body 10 as viewed from the Z-axis direction and is a region interposed between the second electrode 6 and the third electrode 7 in the optical waveguide body 10.

The separation region 17 is formed in the optical waveguide body 10 along a face perpendicular to the optical waveguide direction A at a position corresponding to the gap S1 (the position in the optical waveguide direction A). The separation region 17 reaches the first clad layer 11 from a front face 15a of the second clad layer 15 in the Z-axis direction, and reaches side faces 10a and 10a of the optical waveguide body 10 in the ridge structure in the Y-axis direction. The thickness (the width in the optical waveguide direction A) of the separation region 17 is about 10 to 50 μm.

The separation region 17 is configured with an ion implantation region. The ion implantation region is formed, for example, by adding protons, boron, carbon ions, oxygen ions, nitrogen ions, and the like to the optical waveguide body 10 by ion implantation. The separation region 17 may be configured with an impurity diffusion region. A deep level is formed in the impurity diffusion region by impurity doping. The impurity diffusion region is formed by doping the optical waveguide body 10 with iron, oxygen, chromium, or the like by, for example, thermal diffusion or ion implantation. Alternatively, the separation region 17 may be configured with a semiconductor region having a conductivity type different from that of the second clad layer 15. For example, in this example, since the second clad layer 15 is a p-type semiconductor, the separation region 17 may be configured with an n-type semiconductor region. In any case, the separation region 17 is not an air gap, but separation region 17 is configured with a physical region made of a solid.

The length of the first region 101 in the optical waveguide direction A is larger than the length of the second region 102 in the optical waveguide direction A. The length of the first region 101 in the optical waveguide direction A is, for example, about 1.0 to 2.0 mm. The length of the second region 102 in the optical waveguide direction A is, for example, about 0.5 to 1.0 mm.

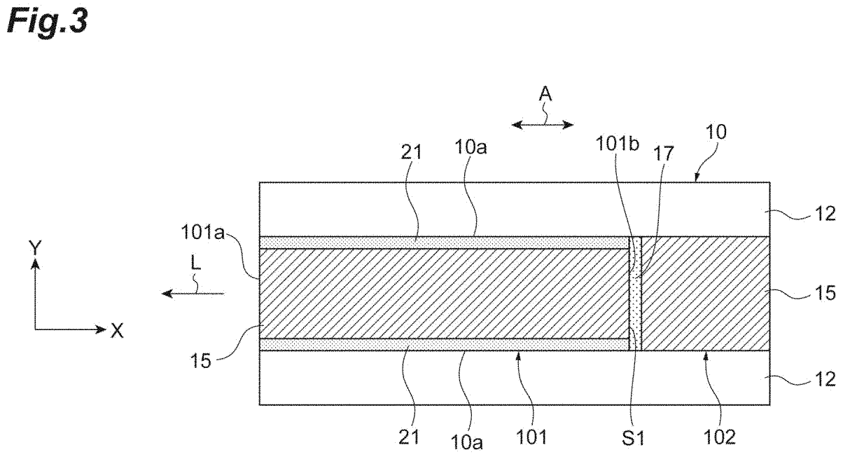

A low reflection layer 8 is provided on an end face 101a of the first region 101 opposite to the second region 102. The end face 101a is an emission face of output light L and is a face perpendicular to the optical waveguide direction A. The low reflection layer 8 suppresses a portion of the output light L from being reflected by the end face 101a and returning to the inside of the optical waveguide body 10. The low reflection layer 8 is, for example, a dielectric multilayer film referred to as an AR coating. In FIGS. 1 and 3, the low reflection layer 8 is omitted in illustration.

The active layer 13 is provided with a pair of limitation regions 21 extending along the optical waveguide direction A. The pair of limitation regions 21 are disposed parallel to each other so as to face each other in the Y-axis direction. In other words, the pair of limitation regions 21 face each other in the width direction (Y-axis direction) perpendicular to both of the optical waveguide direction A (X-axis direction) and the facing direction (Z-axis direction, the thickness direction of the active layer) of the first clad layer 11 and the second clad layer 15. The width (length in the Y-axis direction) of each limitation region 21 is, for example, about 1.0 to 10.0 μm and is about 5 to 20% of the width of the active layer 13. The width of each limitation region 21 is smaller than the distance between the pair of limitation regions 21. The limitation region 21 has, for example, a rectangular cross section, but the limitation region 21 may have any cross section.

One end of the limitation region 21 in the optical waveguide direction A reaches the end face 101a of the first region 101, which is the light emission face of the optical waveguide body 10, and the other end reaches a end face 101b of the first region 101 opposite to the end face 101a. That is, the limitation region 21 extends over the entire first region 101 in the optical waveguide direction A. In addition, the limitation region 21 is provided only in the first region 101 and does not reach the second region 102.

The limitation region 21 also extends along the Z-axis direction. The limitation region 21 reaches each of the first clad layer 11 and the second clad layer 15 from the active layer 13 in the Z-axis direction. As an example, the limitation region 21 is formed at a position corresponding to the separation region 17 in the Z-axis direction, and the upper end (the end on the first electrode 5 side) of the limitation region 21 reaches the front face 15a of the second clad layer 15.

In the present embodiment, the pair of limitation regions 21 are respectively disposed at the side faces 10a and 10a of the optical waveguide body 10 and are exposed to the outside of the optical waveguide body 10. In other words, the pair of limitation regions 21 are disposed along both edges of the active layer 13 (the optical waveguide body 10) in the Y-axis direction respectively (so as to include each of both edges). The pair of limitation regions 21 are disposed symmetrically with respect to a plane passing through the center of the active layer 13 and perpendicular to the Y-axis direction (the width direction of the active layer and the optical waveguide body). The pair of limitation regions 21 partition the active layer 13 in the Y-axis direction. In the present embodiment, the pair of limitation regions 21 are disposed at the side faces 10a and 10a of the optical waveguide body 10 to partition the active layer 13 into one region in the Y-axis direction.

The limitation region 21 is configured with an ion implantation region. The ion implantation region is formed, for example, by adding protons, boron, carbon ions, oxygen ions, nitrogen ions, and the like to the optical waveguide body 10 by ion implantation. Alternatively, the limitation region 21 may be configured with an impurity diffusion region. A deep level is formed in the impurity diffusion region by impurity doping. The impurity diffusion region is formed by doping the optical waveguide body 10 with iron, oxygen, chromium, or the like by, for example, thermal diffusion or ion implantation.

In the limitation region 21, generation of carriers is limited, and carriers are less likely to be generated than in regions other than the limitation region 21 in the active layer 13. That is, in a case where a voltage of the same magnitude is applied to each of the limitation region 21 and the regions other than the limitation region 21 in the active layer 13, the amount of carriers generated per unit volume/unit time in the limitation region 21 is smaller than the amount of carriers generated per unit volume/unit time in the regions other than the limitation region 21 in the active layer 13. This is because a depletion layer is introduced into the limitation region 21 by ion implantation, and in the limitation region 21, the injected current is suppressed from to be effective carriers. Alternatively, in a case where the limitation region 21 is configured with the impurity diffusion region, the resistance of the limitation region 21 is made high, and the amount of current flowing into the limitation region 21 is limited. It is acceptable if the limitation region 21 can limit generation of carriers, and the limitation region 21 may be configured with a region different from the ion implantation region and the impurity diffusion region.

In the SLD 1 configured as described above, a forward bias is applied between the first electrode 5 and the third electrode 7. Specifically, a positive voltage (for example, +1.5 to +3 V) is applied to the first electrode 5 by setting the third electrode 7 to the ground potential. Accordingly, the first region 101 functions as a gain region, and the gain region attempts to oscillate light as a laser diode. On the other hand, a reverse bias is applied between the second electrode 6 and the third electrode 7. Specifically, a negative voltage (for example, −5 V) is applied to the second electrode 6 by setting the third electrode 7 to the ground potential. Accordingly, the second region 102 functions as a loss region, and the loss region attempts to stop light oscillation as a laser diode. Therefore, the first region 101 and the second region 102 function as an SLD and generate the output light L having excellent light condensing property and having a wide spectrum.

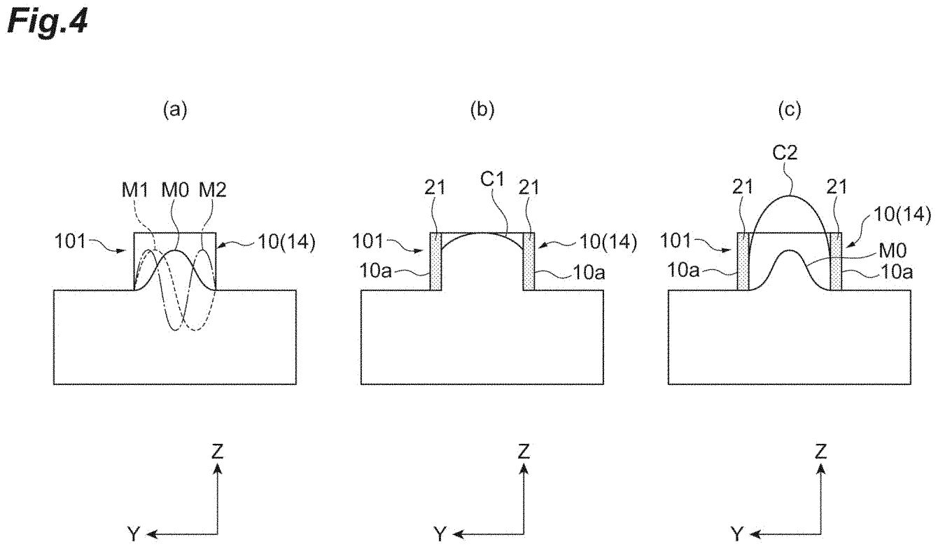

FIG. 4(a) to FIG. 4(c) are conceptual views for describing the functions and effects of the SLD 1. FIG. 4(a) illustrates a mode occurring in the active layer 13 (the optical waveguide body 10) in a case where the first region 101 functions as a gain region in the configuration in which the limitation region 21 is not provided unlike the SLD 1 of the present embodiment. As illustrated in FIG. 4(a), in a case where the limitation region 21 is not provided, the light of a basic mode M0 and the light of the higher-order mode may be mixed in the active layer 13. FIG. 4(a) illustrates, as an example, waveforms of a primary mode M1 and a secondary mode M2 in addition to the basic mode M0. In such a case, the intensity distribution of the output light L on the light emission face, that is, the near-field image may be disturbed by the interference of the light of the plurality of modes with each other.

On the other hand, in the SLD 1 of the present embodiment, since the limitation regions 21 are disposed so that the mode occurring in the active layer 13 is regulated, the output light L having a good beam pattern can be generated. Hereinafter, this point will be described in detail.

FIG. 4(b) illustrates a distribution C1 of the gain coefficient g in a case where the first region 101 functions as the gain region in the SLD 1 of the present embodiment, and FIG. 4(c) illustrates a distribution C2 of the gain G in this case. The gain coefficient g is a value corresponding to a gain obtained while the light travels in a certain area (for example, the first region 101) by a unit distance. The gain coefficient g can be regarded as a value obtained by multiplying the absorption coefficient of the region by −1. When the product of the gain coefficient g and the length of the region in the optical waveguide direction A is denoted by a gain amount gL and the confinement coefficient in the active layer 13 is denoted by Γ, the gain G obtained by light passing through the region along the optical waveguide direction A is obtained from the formula G=exp (ΓgL). The gain amount gL corresponds to the gain obtained by the light when the light passes through the region along the optical waveguide direction A. The gain coefficient g increases as the current density increases. The gain coefficient g can be considered to be proportional to the current density. The current density of a certain region is a value obtained by dividing an injection current into the region by the area of the region as viewed from the Z-axis direction.

As illustrated in FIG. 4(b), even if a voltage is uniformly applied (even if a current is uniformly injected) to the first region 101, since generation of carriers is limited in the limitation region 21, in the vicinity of the side faces 10a and 10a of the optical waveguide body 10 at which the limitation region 21 is disposed, the gain coefficient g is small compared to the central portion in the Y-axis direction where the limitation region 21 is not disposed. As illustrated in FIG. 4(c), this tendency is more prominent in the distribution of the gain G As a result, in the SLD 1 of the present embodiment, the basic mode M0 is dominant (the basic mode M0 is emphasized) as compared with the higher-order mode, and the output light L having a unimodal beam pattern corresponding to the basic mode M0 can be generated. Therefore, even in a case where the optical waveguide body 10 is formed to be wide in order to achieve the high output, the output light L having a good beam pattern can be generated. Therefore, according to the SLD 1, it is possible to achieve both high output and generation of the output light having a good beam pattern.

In the SLD 1, a pair of limitation regions 21 are symmetrically disposed with respect to a plane passing through the center of the active layer 13 and perpendicular to the Y-axis direction. Accordingly, the mode occurring in the active layer 13 can be appropriately regulated by the limitation region 21.

The SLD 1 includes a pair of limitation regions 21 disposed along both edges of the active layer 13 in the Y-axis direction respectively. Accordingly, the mode occurring in the active layer 13 can be more appropriately regulated by the limitation region 21.

In the SLD 1, the limitation regions 21 reach the end face 101a of the first region 101, which is the light emission face of the optical waveguide body 10, in the optical waveguide direction A. Thus, the mode can be regulated in the region including the light emission face side of the active layer 13, and the output light L having a better beam pattern can be generated.

In the SLD 1, the limitation regions 21 reach each of the first clad layer 11 and the second clad layer 15 from the active layer 13 in the Z-axis direction. Accordingly, the mode occurring in the active layer 13 can be more appropriately regulated by the limitation region 21.

In the SLD 1, the limitation regions 21 are configured with an ion implantation region or an impurity diffusion region. Accordingly, generation of carriers in the limitation regions 21 can be appropriately limited.

In the SSLD 1, the optical waveguide direction A is a direction that extends straight. As a result, it is possible to generate the output light L having a better beam pattern.

In the SLD 1, the end face 101a of the first region 101, which is the light emission face of the optical waveguide body 10, is a face perpendicular to the optical waveguide direction A. Accordingly, it is possible to generate the output light L having a better beam pattern.

In the SLD 1, the optical waveguide body 10 is configured to have a ridge structure on the substrate 2. Accordingly, the handling of the SLD 1 can be facilitated, and the configuration of the optical waveguide body 10 can be simplified.

In the SLD 1, the optical waveguide body 10 is provided with the separation region 17 that optically connects the first region 101 below the first electrode 5 and the second region 102 below the second electrode 6 and electrically separates the first region 101 and the second region 102 from each other. Accordingly, a forward bias is applied between the first electrode 5 and the third electrode 7 to allow the first region 101 to function as a gain region, and a reverse bias is applied between the second electrode 6 and the third electrode 7 to allow the second region 102 to function as a loss region, so that the output light L having a good beam pattern can be generated.

In the SLD 1, the limitation regions 21 are provided in the first region 101 and do not reach the second region 102. Thus, since the second region 102 is not provided with the limitation regions 21, in a state where the first region 101 functions as a gain region and the second region 102 functions as a loss region, light generated in the gain region can be effectively absorbed in the loss region.

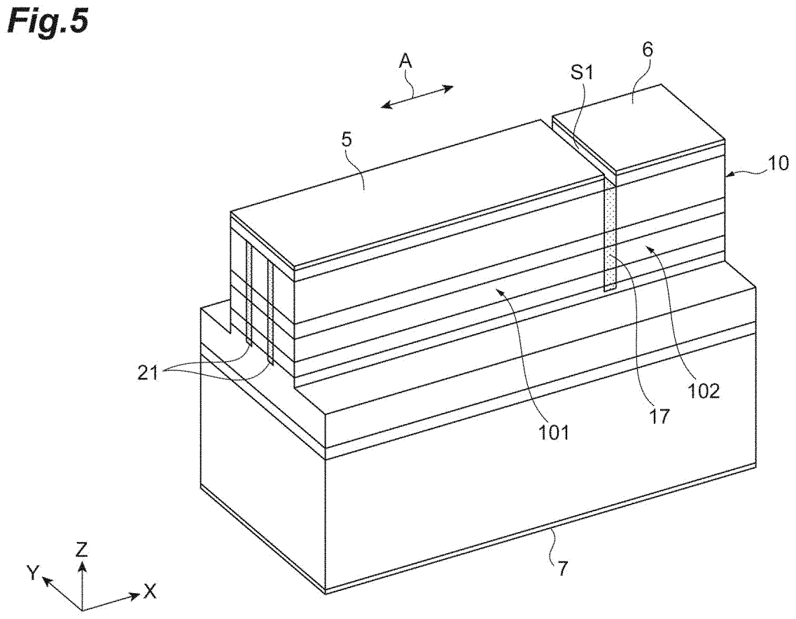

The present disclosure is not limited to the above-described embodiment. For example, the limitation region 21 may be provided as in Modified Example 1 illustrated in FIG. 5. In Modified Example 1, the pair of limitation regions 21 are disposed at positions that divide the active layer 13 at equal intervals in the Y-axis direction. More specifically, the pair of limitation regions 21 are disposed at positions that divide the active layer 13 into three portions in the Y-axis direction, and the active layer 13 is partitioned into three regions in the Y-axis direction. In Modified Example 1 as well, the pair of limitation regions 21 are disposed symmetrically with respect to a plane passing through the center of the active layer 13 and perpendicular to the Y-axis direction. “The limitation regions 21 are disposed at positions that divide the active layer 13 at equal intervals in the Y-axis direction” denotes that the center of each limitation region 21 in the Y-axis direction is located at the position.

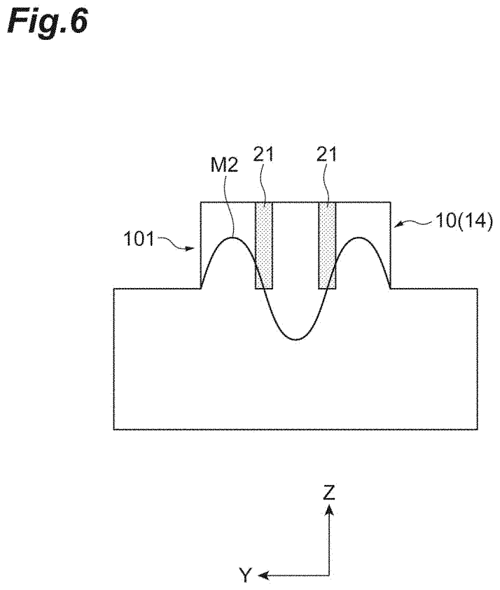

According to Modified Example 1 as well, similarly to the above-described embodiment, since the limitation regions 21 are disposed so that the mode occurring in the active layer 13 is regulated, the output light L having a good beam pattern can be generated. FIG. 6 illustrates a mode occurring in the active layer 13 (optical waveguide body 10) in a case where the first region 101 functions as a gain region in Modified Example 1. As illustrated in FIG. 6, in Modified Example 1, the secondary mode M2 is dominant, and the output light L having a beam pattern corresponding to the secondary mode M2 is obtained. As described above, in a case where the limitation regions 21 are disposed at positions that divide the active layer 13 at equal intervals in the Y-axis direction, the mode occurring in the active layer 13 can be appropriately regulated by the limitation regions 21.

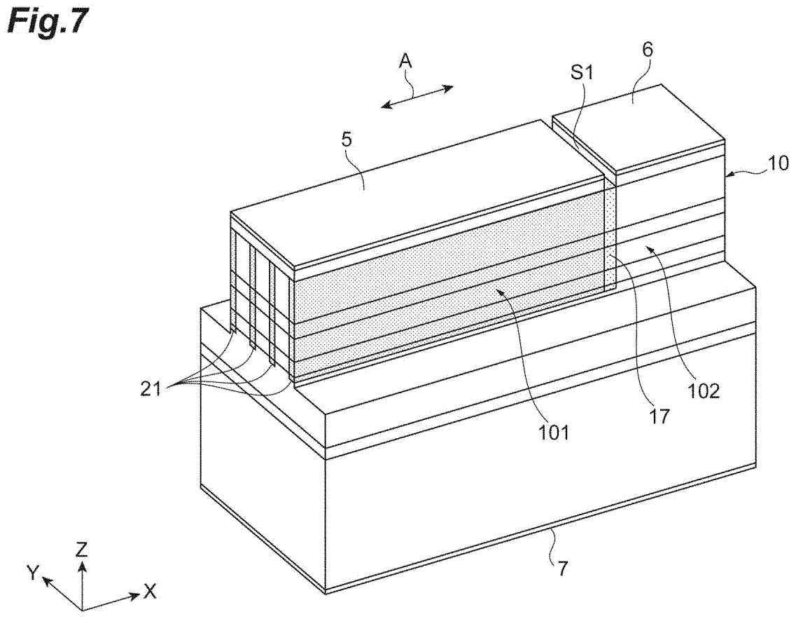

The limitation regions 21 may be provided as in Modified Example 2 illustrated in FIG. 7. In Modified Example 2, four limitation regions 21 are provided. The four limitation regions 21 are disposed at positions that divide the active layer 13 into three equal portions in the Y-axis direction, and the active layer 13 is partitioned into three regions in the Y-axis direction. The four limitation regions 21 are disposed symmetrically with respect to a plane passing through the center of the active layer 13 and perpendicular to the Y-axis direction.

According to Modified Example 2 as well, similarly to the above-described embodiment, since the limitation regions 21 are disposed so that the mode occurring in the active layer 13 is regulated, the output light L having a good beam pattern can be generated. More specifically, also in Modified Example 2, similarly to Modified Example 1, the secondary mode M2 becomes dominant, and the output light L having a beam pattern corresponding to the secondary mode M2 is obtained.

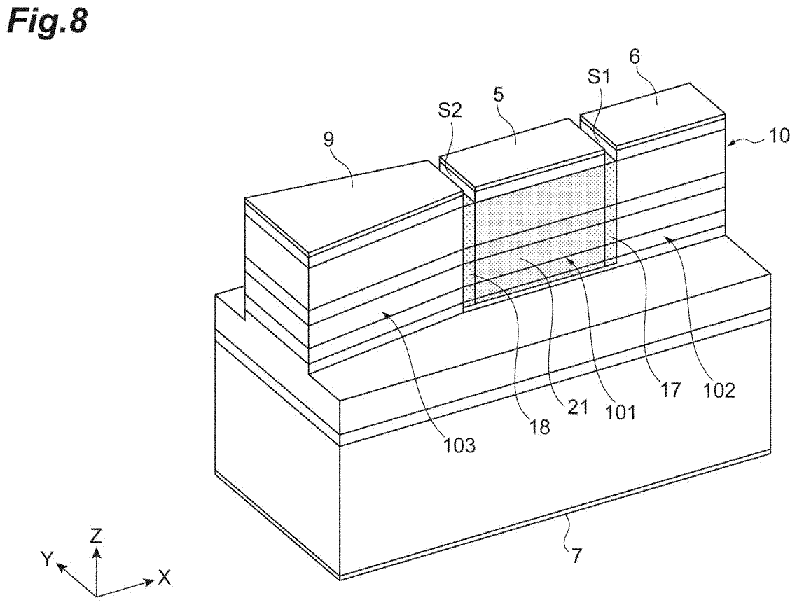

In the above-described embodiment, the optical waveguide body 10 is divided into two regions of the first region 101 and the second region 102. However, as in Modified Example 3 illustrated in FIG. 8, the optical waveguide body 10 may be divided into three regions of the first region 101, the second region 102, and a third region 103. Similarly to the first electrode 5 and the second electrode, the third region 103 is a region below the fourth electrode 9 provided on the second clad layer 15. The fourth electrode 9 is disposed on the side opposite to the second electrode 6 with respect to the first electrode 5 in the optical waveguide direction A. A gap S2 extending in the Y-axis direction is formed between the fourth electrode 9 and the first electrode 5, and the fourth electrode 9 and the first electrode 5 are optically connected and electrically separated by the separation region 18. Similarly to the separation region 17, the separation region 18 is formed by an ion implantation region, but the separation region 18 may be formed by an impurity diffusion region. The third region 103 has a flare shape in which, as viewed from the Z-axis direction, the width increases as the distance from the first region 101 increases. In this example, the width of the third region 103 increases linearly as the distance from the first region 101 increases. The maximum width of the third region 103 is, for example, about 500 μm. The limitation regions 21 are provided similarly to Modified Example 1. The limitation regions 21 are provided only in the first region 101, and the limitation regions 21 do not reach the second region 102 and the third region 103.

According to Modified Example 3 as well, similarly to the above-described embodiment, since the limitation regions 21 are disposed so that the mode occurring in the active layer 13 is regulated, the output light L having a good beam pattern can be generated. More specifically, also in Modified Example 3, similarly to Modified Example 1, the secondary mode M2 is dominant, and the output light L having a beam pattern corresponding to the secondary mode M2 is obtained. In addition, in Modified Example 3, since the light is amplified while spreading in the third region 103, the output light L having a wide beam pattern can be generated. Furthermore, in the third region 103, as the width increases, the current density is reduced, and carriers are less likely to be generated, so that a new mode is less likely to occur. Therefore, according to Modified Example 3, it is possible to generate the output light L having a better beam pattern.

As another modification, the limitation regions 21 may be provided so that the mode occurring in the active layer 13 is regulated, and the number and arrangement of the limitation regions 21 are not limited to the above-described example. For example, one limitation region 21 may be disposed at a position that divides the active layer 13 into two equal portions in the Y-axis direction, and the active layer 13 may be partitioned into two regions in the Y-axis direction. Alternatively, five limitation regions 21 may be disposed at positions that divide the active layer 13 into four equal portions in the Y-axis direction, and the active layer 13 may be partitioned into four regions in the Y-axis direction. The limitation region 21 needs not to reach each of the first clad layer 11 and the second clad layer 15 from the active layer 13 in the Z-axis direction. For example, the limitation region 21 may be provided only in a central portion of the active layer 13 in the Z-axis direction. “The limitation region 21 partitions the active layer 13 in the Y-axis direction” includes not only a case where the limitation region 21 completely separates the active layer 13 into one side and the other side in the Y-axis direction but also a case where the limitation region 21 partially separates the active layer 13 as in the above-described case.

In the above-described embodiment, one end of the limitation region 21 in the optical waveguide direction A may not reach the end face 101a of the first region 101. The other end of the limitation region 21 in the optical waveguide direction A may not reach the end face 101b of the first region 101. Alternatively, the limitation region 21 may extend to reach the second region 102. In Modified Example 3, the limitation region 21 may extend to reach the third region 103. In the plurality of limitation regions 21, the lengths, widths, or thicknesses of the limitation regions 21 may be different from each other.

In the above-described embodiment, one third electrode 7 faces the first electrode 5 and the second electrode 6 as a common electrode, but a plurality of the third electrodes 7 may face the first electrode 5 and the second electrode 6, respectively. In the above-described embodiment, the optical waveguide body 10 is configured as a ridge structure, but the optical waveguide body 10 may be configured as a buried structure. In this case as well, the direction along the center line of the cylindrical region for confining light, in other words, the direction in which the active layer 13 surrounded by the cylindrical region extends is the optical waveguide direction A. The optical waveguide direction A may be a direction extending in a curved manner or may be a direction including both of a portion extending straight and a portion of extending in a curved manner. The optical waveguide direction A may be a direction extending obliquely with respect to the end face 101a of the first region 101.

In the above-described embodiment, the separation region 17 may not be provided, and the first region 101 and the second region 102 may be provided continuously and integrally. In Modified Example 3, the separation region 17 may not be provided, and the first region 101 and the third region 103 may be formed continuously and integrally. The materials and shapes of the respective components are not limited to the materials and shapes described above, and various materials and shapes can be employed.

In the above-described embodiment, the output light L is generated by allowing the first region 101 to function as a gain region and allowing the second region 102 to function as an absorption region. However, the output light L may be generated by other configurations. In this case, the second region 102 may not be provided. For example, a low reflection layer may be provided on each of both end faces of the optical waveguide body 10 in the optical waveguide direction A, and the output light L may be generated by suppressing the resonance of light by the low reflection layer. Alternatively, the output light L may be generated by suppressing the resonance of light by setting the optical waveguide direction A as a direction extending obliquely with respect to the end face 101a of the first region 101 or a direction including a portion extending in a curved manner.

### REFERENCE SIGNS LIST

1: superluminescent diode, 2: substrate, 5: first electrode, 6: second electrode, 7: third electrode, 8: low reflection layer, 9: fourth electrode, 10: optical waveguide body, 11: first clad layer, 13: active layer, 15: second clad layer, 15a: front face, 17: separation region, 21: limitation region, 101: first region, 101a: end face (light emission face), 102: second region, 103: third region, A: optical waveguide direction.

1. A superluminescent diode comprising:
an optical waveguide body configured as a double heterostructure including an active layer and a first clad layer and a second clad layer interposing the active layer,
wherein, when a direction perpendicular to both an optical waveguide direction of the optical waveguide body and a facing direction of the first clad layer and the second clad layer is set as a width direction, the active layer is provided with a limitation region extending along the optical waveguide direction and partitioning the active layer in the width direction, and
wherein carriers are less likely to be generated in the limitation region than in a region other than the limitation region in the active layer.

2. The superluminescent diode according to claim 1,
wherein a plurality of the limitation regions are provided, and
wherein the plurality of limitation regions are disposed symmetrically with respect to a plane passing through a center of the active layer and perpendicular to the width direction.

3. The superluminescent diode according to claim 1,
wherein a plurality of the limitation regions are provided, and
wherein the plurality of limitation regions include a pair of the limitation regions disposed along both edges of the active layer in the width direction respectively.

4. The superluminescent diode according to claim 1, wherein the limitation region is disposed at a position that divides the active layer at equal intervals in the width direction.

5. The superluminescent diode according to claim 1, wherein the limitation region reaches a light emission face of the optical waveguide body in the optical waveguide direction.

6. The superluminescent diode according to claim 1, wherein the limitation region reaches each of the first clad layer and the second clad layer from the active layer in the facing direction.

7. The superluminescent diode according to claim 1, wherein the limitation region is configured with an ion implantation region or an impurity diffusion region.

8. The superluminescent diode according to claim 1, wherein the optical waveguide direction is a direction extending straight.

9. The superluminescent diode according to claim 1, wherein a light emission face of the optical waveguide body is a face perpendicular to the optical waveguide direction.

10. The superluminescent diode according to claim 1, further comprising a substrate provided with the optical waveguide body,
wherein the optical waveguide body is configured as a ridge structure on the substrate.

11. The superluminescent diode according to claim 1, further comprising:
a first electrode and a second electrode that are provided on the second clad layer so as to be arranged along the optical waveguide direction; and
at least one third electrode facing the first electrode and the second electrode with the optical waveguide body interposed therebetween,
wherein the optical waveguide body is provided with a separation region that optically connects a first region below the first electrode and a second region below the second electrode and electrically separates the first region and the second region from each other.

12. The superluminescent diode according to claim 11, wherein the limitation region is provided in the first region and does not reach the second region.

13. The superluminescent diode according to claim 11, further comprising a fourth electrode provided on the second clad layer so as to be located on a side opposite to the second electrode with respect to the first electrode in the optical waveguide direction,
wherein a third region below the fourth electrode has a flare shape in which, as viewed from the facing direction of the first clad layer and the second clad layer, the width increases as the distance from the first region increases.
